(19) United States
(12) Patent Application Publication
(10) Pub. No.: US 2007/0018309 A1
(43) Pub. Date: Jan. 25, 2007

(54) Image sensor package, optical glass used therein, and processing method of the optical glass

(75) Inventors: Cheng Yi Chang, Taichung Hsien (TW); Chih Ming Huang, Hsinchu Hsein (TW); Yu Po Wang, Taichung Hsien (TW); Chien Ping Huang, Hsinchu Hsien (TW); Cheng Hsu Hsiao, Taichung Hsien (TW)

Correspondence Address: EDWARDS & ANGELL, LLP, P.O. BOX 55874, BOSTON, MA, 02205, US

(73) Assignee: Siliconware Precision Industries Co., Ltd., Taichung (TW)

(21) Appl. No.: 11/431,715

(22) Filed: May 9, 2006

(30) Foreign Application Priority Data
Jul. 21, 2005 (TW) 094124646

(51) Int. Cl. H01L 21/00

(52) U.S. Cl. 257/704; 438/26

(57) ABSTRACT

An image sensor package, optical glass used therein, and a processing method of the optical glass are provided. The method includes defining a plurality of cutting paths on a piece of optical glass; grinding the piece of optical glass at the cutting paths to form a rough surface on each of the cutting paths; and cutting the piece of optical glass along the cutting paths into a plurality of optical glass units by a cutting tool, wherein the rough surface is larger in width than the cutting tool, and each of the optical glass units has the rough surface on at least one edge thereof. The optical glass unit is attached via an adhesive layer to a supporting member on a chip carrier mounted with a sensor chip, and provides good adhesion between the optical glass unit and the adhesive layer via the rough surface.

### FIELD OF THE INVENTION

The present invention relates to image sensor packages, optical glass used therein, and processing methods of the optical glass, and more particularly, to an image sensor package with an optical glass unit and a method of processing and forming the optical glass unit.

### BACKGROUND OF THE INVENTION

Conventional image sensor package, as shown in FIG. 1, includes a chip carrier 10; a ring-shaped supporting member 11 mounted on the chip carrier 10 and having a receiving space therein; a sensor chip 12 disposed in the receiving space of the supporting member 11 and on the chip carrier 10, and electrically connected to the chip carrier 10 by bonding wires 13; and an optical glass unit 15 attached to the supporting member 11 via an adhesive layer 14, for covering the sensor chip 12 and sealing the receiving space. The optical glass unit 15 protects the sensor chip 12 against external contaminants and allows light to pass through the optical glass unit 15 to a sensor region 120 of the sensor chip 12. The image sensor package is applicable to various electronic devices such as digital still camera (DSC), digital video camera (DV), optical mouse, mobile phone, fingerprint recognizer, and so on. Prior arts related to the image sensor package include U.S. Pat. Nos. 6,353,257; 6,384,472; 6,740,967; 6,268,231; 6,285,064; and 6,603,183.

The above conventional image sensor package can be fabricated by a method shown in FIGS. 2A to 2E. Firstly, referring to FIGS. 2A and 2B, a piece of optical glass 25 is attached to a tape 27 on which a wafer ring 26 is mounted peripherally. Next, referring to FIG. 2C, the piece of optical glass 25 is cut into a plurality of optical glass units 250. Then, referring to FIGS. 2D and 2E, each optical glass unit 250 is lifted and moved by a clamping or sucking device 28 to be attached via an adhesive layer 24 to a supporting member 21 that is mounted on a chip carrier 20, allowing the optical glass unit 250 to cover a sensor chip 22 mounted on the chip carrier 20, such that the image sensor package is completed.

The above optical glass needs to have high transmittance and smooth surfaces in order to ensure the light passing through the optical glass to be effectively captured by the sensor chip. However, such optical glass with smooth surfaces is not capable of being effectively attached to the adhesive layer and thus cannot be firmly fixed to the supporting member. Moreover, the optical glass has a coefficient of thermal expansion (CTE) different from that of the supporting member, thereby easily resulting in delamination between the optical glass and the supporting member due to thermal stress. The delamination further leads to invasion of moisture and contaminants into the package, such that the light receiving ability of the sensor chip is adversely affected and, reliability of the image sensor package is degraded.

Therefore, the problem to be solved here is to provide an image sensor package for overcoming the foregoing drawbacks in the prior art.

### SUMMARY OF THE INVENTION

In light of the foregoing drawbacks in the prior art, an objective of the present invention is to provide an image sensor package, optical glass used therein, and a processing method of the optical glass, so as to improve adhesion between the optical glass and an adhesive layer in the image sensor package. Another objective of the present invention is to provide an image sensor package, optical glass used therein, and a processing method of the optical glass, so as to reduce delamination of the optical glass in the image sensor package.

A further objective of the present invention is to provide an image sensor package, optical glass used therein, and a processing method of the optical glass, so as to prevent moisture and contaminants from entering an internal space covered by the optical glass in the image sensor package.

In order to achieve the foregoing and other objectives, the present invention proposes a processing method of optical glass for use in an image sensor package, comprising the steps of: preparing a piece of optical glass and defining a plurality of cutting paths on the piece of optical glass; grinding the piece of optical glass at the cutting paths by a grinding tool to form a rough surface on each of the cutting paths; and cutting the piece of optical glass along the cutting paths into a plurality of optical glass units by a cutting tool, wherein the rough surface of each of the cutting paths is larger in width than the cutting tool, and each of the optical glass units has the rough surface on at least one edge thereof.

By the foregoing processing method, the present invention proposes an optical glass unit for use in an image sensor package, wherein the optical glass unit is formed with a rough surface on at least one edge thereof, and the optical glass unit can be well adhered via its rough surface to an adhesive layer that is used for attaching the optical glass unit to a supporting member in the image sensor package.

The present invention also proposes an image sensor package, comprising: a chip carrier; a ring-shaped supporting member mounted on the chip carrier and having a receiving space therein; at least one sensor chip disposed in the receiving space of the supporting member and on the chip carrier; and an optical glass unit attached to the supporting member, for covering the sensor chip and sealing the receiving space, wherein the optical glass unit is formed with a rough surface on at least one edge thereof and is attached via its rough surface to the supporting member by an adhesive layer.

Therefore, by the image sensor package, the optical glass used therein, and the processing method of the optical glass as proposed in the present invention, the plurality of cutting paths defined on the piece of optical glass are each ground to form the rough surface, and then the piece of optical glass is cut along the cutting paths into the plurality of optical glass units, such that each of the optical glass units is formed with the rough surface on at least one edge thereof The rough surface of each optical glass unit improves adhesion between the optical glass unit and the adhesive layer that is used for attaching the optical glass unit to the supporting member in the image sensor package, such that the optical glass unit can be firmly fixed to the supporting member via the adhesive layer. This thereby reduces delamination between the optical glass unit and the supporting member due to thermal stress generated as a result of mismatch in CTE between the optical glass unit and the supporting member, and also prevents moisture and contaminants from entering the receiving space sealed by the optical glass unit, such that the light receiving ability of the sensor chip is assured.

### BRIEF DESCRIPTION OF THE DRAWINGS

The present invention can be more fully understood by reading the following detailed description of the preferred embodiments, with reference made to the accompanying drawings, wherein:

FIG. 1 (PRIOR ART) is a schematic cross-sectional diagram of a conventional image sensor package;

FIGS. 2A to 2E (PRIOR ART) are schematic diagrams showing steps of a conventional processing method of optical glass and a conventional fabrication method of the image sensor package in FIG. 1;

FIGS. 3A to 3D are schematic diagrams showing steps of a processing method of optical glass for use in an image sensor package according to the present invention; and

FIG. 4 is a schematic cross-sectional diagram of the image sensor package according to the present invention.

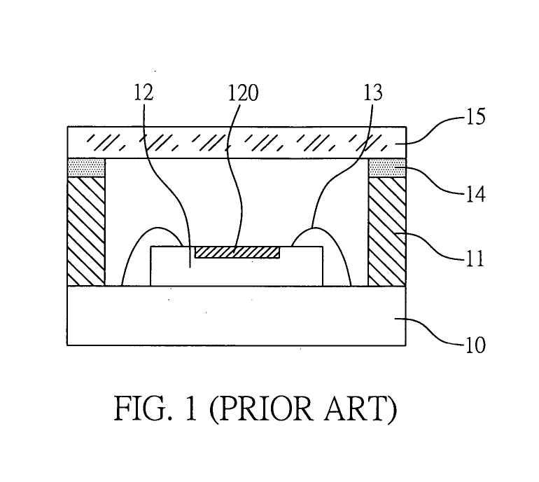

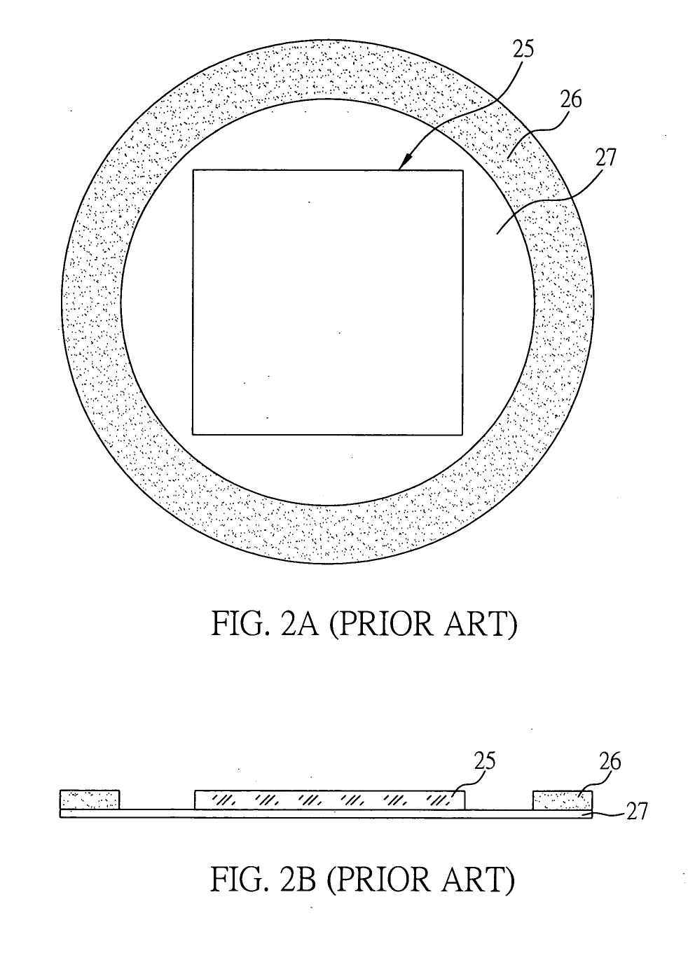

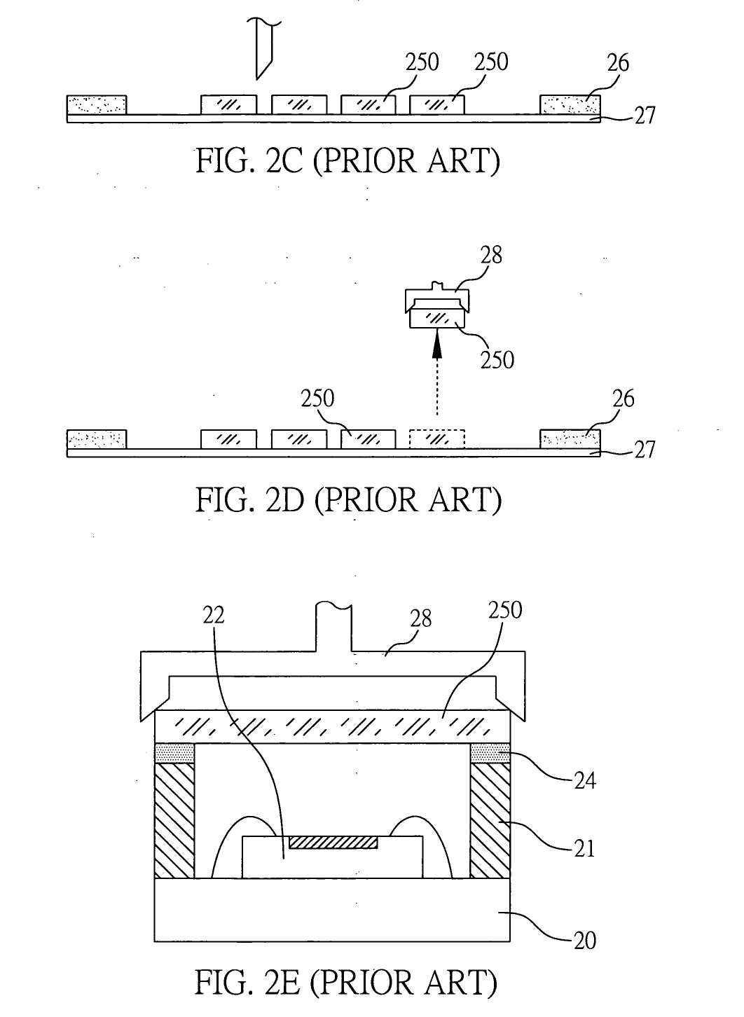

### DETAILED DESCRIPTION OF THE PREFERRED EMBODIMENTS

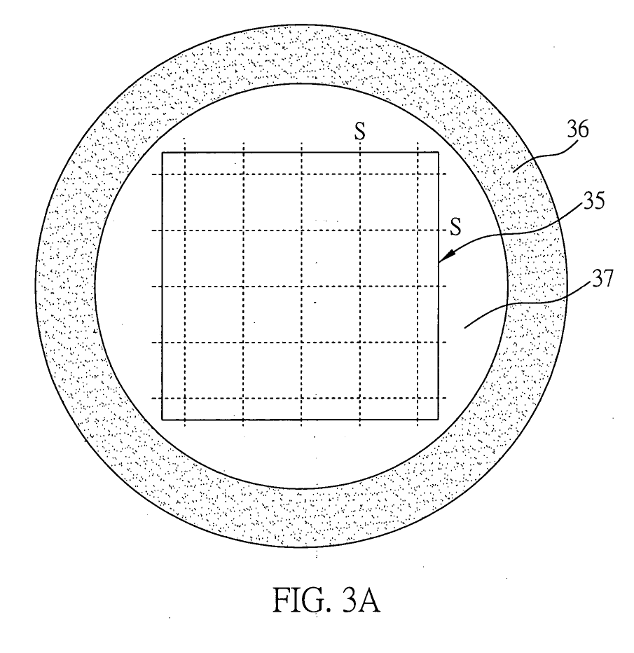

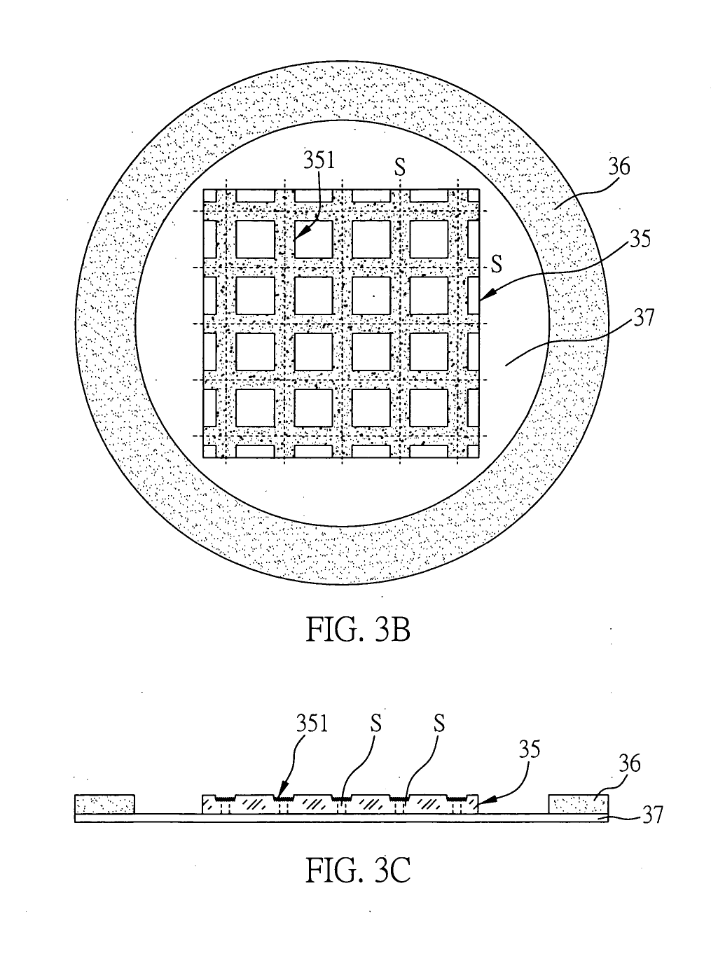

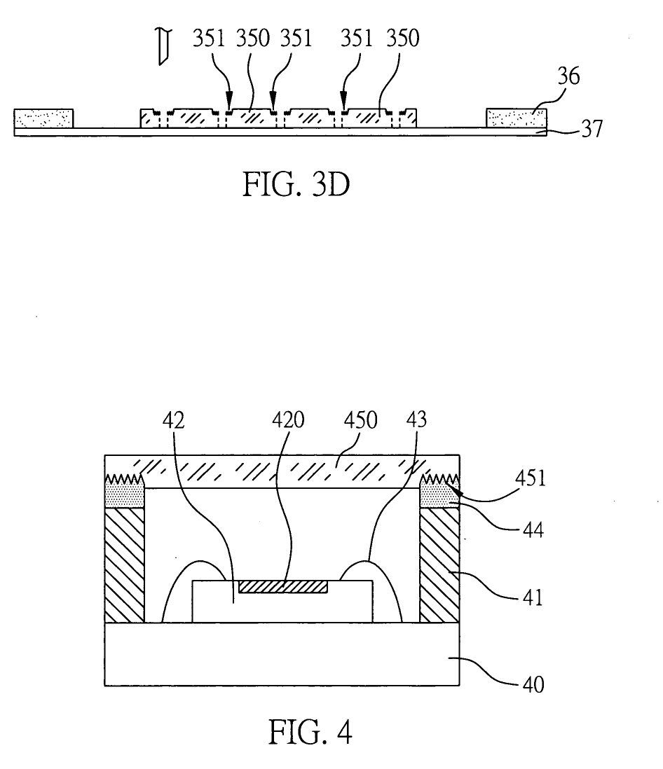

Preferred embodiments of an image sensor package, optical glass used therein, and a processing method of the optical glass as proposed in the present invention are described as follows with reference to FIGS. 3A to 3D and 4. It should be noted that the drawings are simplified schematic diagrams only showing relevant components for the present invention and the component layout can be more complex in practical implementation.

FIGS. 3A to 3D show steps of the processing method of the optical glass for use in the image sensor package of the present invention.

As shown in FIG. 3A, a piece of optical glass 35 is provided on which a plurality of cutting paths S are defined to border a plurality of optical glass units that are to be subsequently formed. The piece of optical glass 35 is adhered to a tape 37 on which a wafer ring 36 is mounted peripherally, and is surrounded by the wafer ring 36.

As shown in FIG. 3B, a grinding process is performed using a grinding tool, such as a grinding roller, to grind the piece of optical glass 35 at the cutting paths S and form a rough surface 351 on each of the cutting paths S.

As shown in FIG. 3C, which is a cross-sectional view of the piece of optical glass 35 of FIG. 3B, a grinding depth of each of the cutting paths S is about 1 to 10 μm, preferably 5 μm, that is, the rough surface 351 is located about 1 to 10 μm (preferably 5 μm) deep from a top surface of the piece of optical glass 35, and a width of the rough surface 351 is about 0.5 to 2 mm.

As shown in FIG. 3D, a cutting tool is used to cut the piece of optical glass 35 along the cutting paths S into a plurality of optical glass units 350, wherein the width of the rough surface 351 of each of the cutting paths S is larger than the width of the cutting tool, and each of the optical glass units 350 has the rough surface 351 on at least one edge thereof

It should be noted that the grinding tool and the cutting tool described in the present invention can be integrated into one device, such that the grinding process and the cutting process can be simultaneously performed in a manner that the piece of optical glass are ground and cut along the cutting paths simultaneously, thereby increasing the processing speed for the optical glass.

By the foregoing processing method, the optical glass unit 350 (as shown in FIG. 3D) for use in an image sensor package is disclosed in the present invention and has the rough surface 351 formed on at least one edge thereof to provide better adhesion between the optical glass unit 350 and an adhesive layer in the image sensor package.

FIG. 4 shows the image sensor package of the present invention, comprising: a chip carrier 40; a ring-shaped supporting member 41 mounted on the chip carrier 40 and having a receiving space therein; a sensor chip 42 disposed in the receiving space of the supporting member 41 and on the chip carrier 40; and an optical glass unit 450 attached to the supporting member 41, for covering the sensor chip 42 and sealing the receiving space, wherein a rough surface 451 is formed on at least one edge of the optical glass unit 450 so as to allow the optical glass unit 450 to be effectively adhered to an adhesive layer 44 via the rough surface 451 and thus firmly attached to the supporting member 41 via the adhesive layer 44. The sensor chip 42 has an active surface and an opposed non-active surface, wherein the active surface of the sensor chip 42 is formed with a sensor region 420 thereon and is electrically connected to the chip carrier 40 via bonding wires 43, and the non-active surface of the sensor chip 42 is attached to the chip carrier 40. The supporting member 41 can be a substrate or made of a resin material.

Therefore, by the image sensor package, the optical glass used therein, and the processing method of the optical glass as proposed in the present invention, the plurality of cutting paths defined on the piece of optical glass are each ground to form the rough surface, and then the piece of optical glass is cut along the cutting paths into the plurality of optical glass units, such that each of the optical glass units is formed with the rough surface on at least one edge thereof The rough surface of each optical glass unit improves adhesion between the optical glass unit and the adhesive layer that is used for attaching the optical glass unit to the supporting member in the image sensor package, such that the optical glass unit can be firmly fixed to the supporting member via the adhesive layer. This thereby reduces delamination between the optical glass unit and the supporting member due to thermal stress generated as a result of mismatch in CTE between the optical glass unit and the supporting member, and also prevents moisture and contaminants from entering the receiving space sealed by the optical glass unit, such that the light receiving ability of the sensor chip is assured.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A processing method of optical glass for use in an image sensor package, comprising the steps of:
preparing a piece of optical glass and defining a plurality of cutting paths on the piece of optical glass;
forming a rough surface on each of the cutting paths of the piece of optical glass; and
cutting the piece of optical glass along the cutting paths into a plurality of optical glass units by a cutting tool, wherein the rough surface of each of the cutting paths has a width larger than that of the cutting tool, and each of the optical glass units has the rough surface on at least one edge thereof.

2. The processing method of claim 1, wherein the rough surface of each of the cutting paths is formed by using a grinding tool to grind the piece of optical glass at the cutting paths.

3. The processing method of claim 2, wherein the grinding tool and the cutting tool are integrated into one device to increase processing speed for the optical glass.

4. The processing method of claim 1, wherein a depth of the rough surface of each of the cutting paths is from 1 to 10 μm.

5. The processing method of claim 4, wherein the depth of the rough surface of each of the cutting paths is 5 μm.

6. The processing method of claim 1, wherein the width of the rough surface of each of the cutting paths is from 0.5 to 2 mm.

7. The processing method of claim 1, wherein the piece of optical glass is attached to a tape on which a wafer ring is mounted peripherally, and is surrounded by the wafer ring.

8. Optical glass for use in an image sensor package, comprising an optical glass unit formed with a rough surface on at least one edge thereof so as to improve adhesion between the optical glass unit and an adhesive layer in the image sensor package via the rough surface.

9. The optical glass of claim 8, wherein a depth of the rough surface is from 1 to 10 μm.

10. The optical glass of claim 9, wherein the depth of the rough surface is 5 μm.

11. An image sensor package comprising:
a chip carrier;
a ring-shaped supporting member mounted on the chip carrier and having a receiving space therein;
at least one sensor chip disposed in the receiving space of the supporting member and on the chip carrier; and
an optical glass unit attached to the supporting member, for covering the sensor chip and sealing the receiving space of the supporting member, wherein a rough surface is formed on at least one edge of the optical glass unit, and the optical glass is attached via the rough surface to the supporting member by an adhesive layer.

12. The image sensor package of claim 11, wherein a depth of the rough surface is from 1 to 10 μm.

13. The image sensor package of claim 12, wherein the depth of the rough surface is 5 μm.

14. The image sensor package of claim 11, wherein the sensor chip has an active surface and an opposed non-active surface, with the active surface being formed with a sensor region thereon and electrically connected to the chip carrier via bonding wires, and with the non-active surface being attached to the chip carrier.
